(19) United States
(12) Patent Application Publication
(10) Pub. No.: US 2026/0310856 A1
(43) Pub. Date: Oct. 8, 2026

(54) THREE-DIMENSIONAL SHAPE GENERATION USING ORTHOGONAL MULTI-VIEW SKETCHES

(71) Applicant: AUTODESK, INC., San Francisco, CA (US)

(72) Inventor: Bruno ROY, Longueuil (CA)

(21) Appl. No.: 19/410,920

(22) Filed: Dec. 5, 2025

Related U.S. Application Data
(60) Provisional application No. 63/783,894, filed on Apr. 4, 2025.

(51) Int. Cl. G06F 30/27; G06T 5/70

(52) U.S. Cl. CPC G06F 30/27; G06T 5/70

(57) ABSTRACT

One embodiment sets forth a technique for generating three-dimensional shapes includes receiving one or more orthogonal multi-view sketches and one or more per-view annotations; performing, using a first trained machine learning model and a second trained machine learning model, one or more denoising operations to generate one or more multi-view images based on the one or more orthogonal multi-view sketches and the one or more per-view annotations; generating, based on the one or more orthogonal multi-view sketches and the one or more per-view annotations, a volumetric prior; performing, based on the one or more multi-view images and the volumetric prior, one or more optimization operations to optimize a shape model; and generating a three-dimensional shape based on the shape model.

### CROSS-REFERENCE TO RELATED APPLICATIONS

This application claims priority benefit of the United States Provisional Patent Application titled, “TECHNIQUES FOR IMPLEMENTING MULTI-MODAL 3D SHAPE GENERATION USING ORTHOGONAL SKETCHES,” filed on Apr. 4, 2025, and having Ser. No. 63/783,894. The subject matter of this related application is hereby incorporated herein by reference.

### BACKGROUND

### Technical Field

Embodiments of the present disclosure relate generally to computer graphics, content generation, artificial intelligence, and machine learning, and, more specifically, to techniques for three-dimensional shape generation using orthogonal multi-view sketches.

### Description of the Related Art

Three-dimensional shape generation refers to the computational generation of digital geometric representations that define the structure of an object in three-dimensional space. The representations include surfaces, volumetric fields, meshes, implicit functions, and other geometric forms used to show physical or conceptual objects. Shape generation is used in a wide range of domains, including digital content generation, product modeling, animation, virtual environments, simulation, engineering design, and/or the like. For example, digital shapes can be generated to represent characters, manufactured components, architectural structures, environmental assets, and other geometric elements used in visualization, analysis, or interactive applications.

Conventional approaches for three-dimensional shape generation increasingly employ generative modeling techniques in which two-dimensional or three-dimensional reference data is used to guide the formation of digital geometric representations (e.g., shapes). Conventional approaches for shape generation often begin with the collection of image data, geometric examples, or annotated reference material relevant to the type of object being generated. Subsequent training or conditioning of a generative model uses such reference data. The generative model establishes a representation of structural patterns, geometric relationships, and spatial characteristics present in the reference data and generates three-dimensional shapes in the form of meshes, volumetric fields, implicit functions, and/or the like. When prompted with new input data or descriptive conditions, the generative model generates corresponding three-dimensional shapes that are incorporated into visualization, animation, simulation, or design workflows.

At least one technical drawback of the foregoing conventional approaches for three-dimensional shape generation is that such approaches rely heavily on direct geometric reconstruction, which is difficult to perform accurately when the available inputs are sparse or imprecise. In particular, approaches that rely on geometric reconstruction often assume access to well-defined contours, clean silhouettes, or dense multi-view data. However, the underlying geometry reconstruction procedures are highly sensitive to noise, small distortions, and inconsistencies across viewpoints. As a result, conventional approaches do not perform reliably when the inputs consist of hand-drawn or freeform sketches, including triplane sketches that artists commonly generate to communicate front, side, and top views of an intended shape. Hence, geometry-focused conventional approaches often fail to generate coherent three-dimensional shapes or require extensive preprocessing to correct for variability inherent in user-generated sketches.

As the foregoing illustrates, what is needed in the art are more effective techniques for three-dimensional shape generation.

### SUMMARY

One embodiment sets forth a computer-implemented method for generating three-dimensional shapes. The method includes receiving one or more orthogonal multi-view sketches and one or more per-view annotations. The method also includes performing, using a first trained machine learning model and a second trained machine learning model, one or more denoising operations to generate one or more multi-view images based on the one or more orthogonal multi-view sketches and the one or more per-view annotations. The method further includes generating, based on the one or more orthogonal multi-view sketches and the one or more per-view annotations, a volumetric prior. Furthermore, the method includes performing, based on the one or more multi-view images and the volumetric prior, one or more optimization operations to optimize a shape model. In addition, the method includes generating a three-dimensional shape based on the shape model.

Other embodiments of the present disclosure include, without limitation, one or more computer-readable media including instructions for performing one or more aspects of the disclosed techniques as well as a computing device for performing one or more aspects of the disclosed techniques.

At least one technical advantage of the disclosed techniques relative to the prior art is that the disclosed techniques do not rely on direct geometric reconstruction or strict multi-view geometric consistency and therefore avoid the heavy computational costs and fragile processing steps associated with conventional geometry-based approaches. Another technical advantage of the disclosed techniques is that the disclosed techniques provide more efficient computation, reduced sensitivity to drawing imperfections, and improved stability across a wide range of sketch inputs, which lowers user effort and enables a shape generation workflow that is more accessible to non-experts. Yet another technical advantage of the disclosed techniques is the reduction of failure cases and the reduction of the need for manual correction, resulting in three-dimensional shape generation that is more user-friendly, more predictable, and more responsive.

These technical advantages provide one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, can be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a block diagram of a computer system configured to implement one or more aspects of various embodiments;

FIG. 2 is a more detailed illustration of the computing device of FIG. 1, according to various embodiments;

FIG. 3 is a more detailed illustration of the shape generation application of FIG. 1, according to various embodiments; and

FIG. 4 is a flow diagram of method steps for generating a shape, according to various embodiments.

### DETAILED DESCRIPTION

In the following description, numerous specific details are set forth to provide a more thorough understanding of the various embodiments. However, it will be apparent to one skilled in the art that the concepts can be practiced without one or more of these specific details.

### General Overview

Embodiments of the present disclosure provide techniques for three-dimensional orthogonal multi-view sketches. In some embodiments, the disclosed techniques include a shape generation application that uses a multi-view diffusion model, a spatial conditioning model, and a shape model to process one or more per-view annotations and one or more orthogonal multi-view sketches and to generate a shape. The multi-view image diffusion model is a machine learning model, such as a diffusion model, that processes a spatial conditioning, the per-view annotations, and a latent representation and generates a refined noise estimate. The spatial conditioning model is a machine learning model, such as a neural network, that processes the latent representation and one or more depth maps and generates the spatial conditioning. The shape model includes a geometric representation of an object included in the multi-view images. The shape generation application includes a multi-view image generator, a volumetric prior generator, and a guided shape model optimizer. The multi-view image generator performs one or more denoising operations, using the multi-view image diffusion model and the spatial conditioning model, to process the per-view annotations and the orthogonal multi-view sketches and to generate one or more multi-view images. The volumetric prior generator processes the per-view annotations and the orthogonal multi-view sketches and generates a volumetric prior. The guided shape model optimizer performs one or more optimization operations to optimize the shape model based on the multi-view images and the volumetric prior and to generate the shape.

The three-dimensional shape generation techniques of the present disclosure have various real-world applications. For example, the disclosed techniques are employed in product development and industrial design to create conceptual geometries, component representations, and structural models across consumer products, mechanical assemblies, and electronic devices. In animation, visual effects, and game production, the disclosed techniques support construction of character models, props, and environmental assets for digital scenes. In robotics and autonomous systems development, the disclosed techniques provide geometric inputs for manipulation planning, simulation, and virtual testing of robot interactions with physical objects. In architecture and spatial design, the disclosed techniques facilitate generation of building elements, interior layouts, and environmental structures for visualization and planning. Additionally, the disclosed techniques can be applied in manufacturing, additive fabrication, and rapid prototyping to generate digital shapes used for verification, optimization, and production-oriented workflows.

The above examples are not in any way intended to be limiting. As persons skilled in the art will appreciate, as a general matter, the virtual object generation techniques described herein can be implemented in any suitable application.

### System Overview

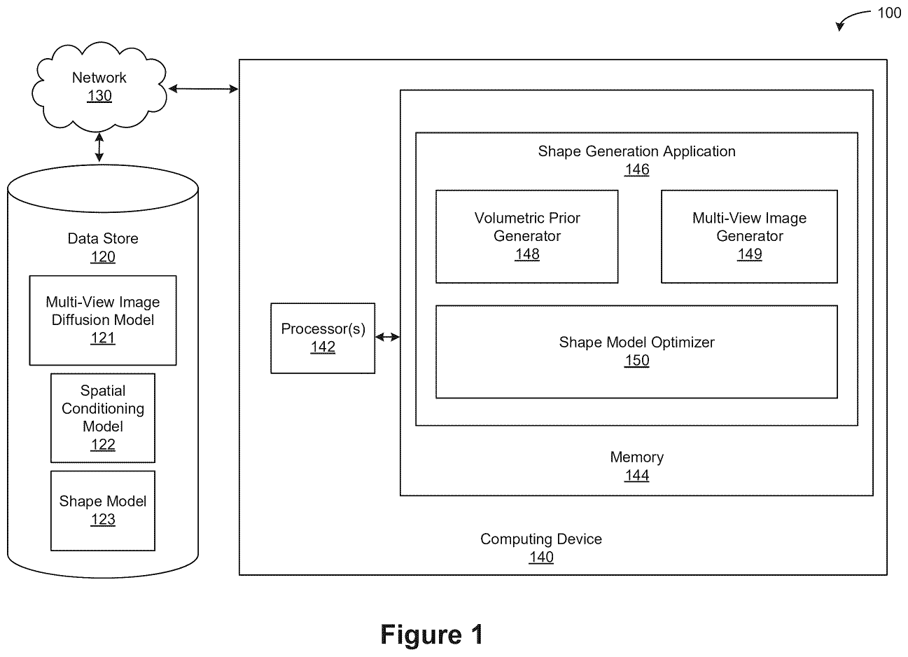

FIG. 1 illustrates a block diagram of a computer-based system 100 configured to implement one or more aspects of at least one embodiment. As shown, system 100 includes a data store 120 and a computing device 140 in communication over a network 130. Network 130 can be a wide area network (WAN) such as the Internet, a local area network (LAN), a cellular network, and/or any other suitable network. Data store 120 includes, without limitation, a multi-view image diffusion model 121, a spatial conditioning model 122, and a shape model 123. Computing device 140 includes, without limitation, processor(s) 142 and a memory 144. Memory 144 includes, without limitation, a shape generation application 146. Shape generation application 146 includes, without limitation, a volumetric prior generator 148, a multi-view image generator 149, and a guided shape model optimizer 150.

Processor(s) 142 receive user input from input devices, such as a keyboard or a mouse. Processor(s) 142 may include one or more primary processors of computing device 140, which control and coordinate operations of other system components. In particular, processor(s) 142 can issue commands that control the operation of one or more graphics processing units (GPUs) (not shown) and/or other parallel processing circuitry (e.g., parallel processing units, deep learning accelerators, etc.) that incorporates circuitry optimized for graphics and video processing, including, for example, video output circuitry. The GPU(s) can deliver pixels to a display device that can be any conventional cathode ray tube, liquid crystal display, light-emitting diode display, and/or similar technologies.

Memory 144 of computing device 140 stores content, such as software applications and data, for use by processor(s) 142 and the GPU(s) and/or other processing units. Memory 144 can be any type of memory capable of storing data and software applications, such as a random-access memory (RAM), a read-only memory (ROM), an erasable programmable read-only memory (EPROM or Flash ROM), or any suitable combination of the foregoing. In some embodiments, a storage (not shown) can supplement or replace the memory 144. The storage can include any number and type of external memories that are accessible to processor(s) 142 and/or the GPU(s). For example, and without limitation, the storage can include a Secure Digital Card, an external Flash memory, a portable compact disc read-only memory (CD-ROM), an optical storage device, a magnetic storage device, and/or any suitable combination of the foregoing.

Computing device 140 shown herein is for illustrative purposes only, and variations and modifications are possible without departing from the scope of the present disclosure. For example, the number of processors 142, the number of GPUs and/or other processing unit types, the number of memories 144, and/or the number of applications included in memory 144 can be modified as desired. Further, the connection topology between the various units in FIG. 1 can be modified as desired. In some embodiments, any combination of processor(s) 142, memory 144, and/or GPUs can be included in and/or replaced with any type of virtual computing system, distributed computing system, and/or cloud computing environment, such as a public, private, or hybrid cloud system.

As shown, shape generation application 146, which uses multi-view image diffusion model 121, spatial conditioning model 122, and shape model 123 stored in data store 120 and accessed over network 130, executes on processor(s) 142 of computing device 140. Shape generation application 146 uses multi-view image diffusion model 121, spatial conditioning model 122, and shape model 123 to process one or more per-view annotations and one or more orthogonal multi-view sketches and generate a shape. Multi-view image generator 149 is a module of shape generation application 146 that performs one or more denoising operations using multi-view image diffusion model 121 and spatial conditioning model 122 to process the per-view annotations and the orthogonal multi-view sketches and generate one or more multi-view images.

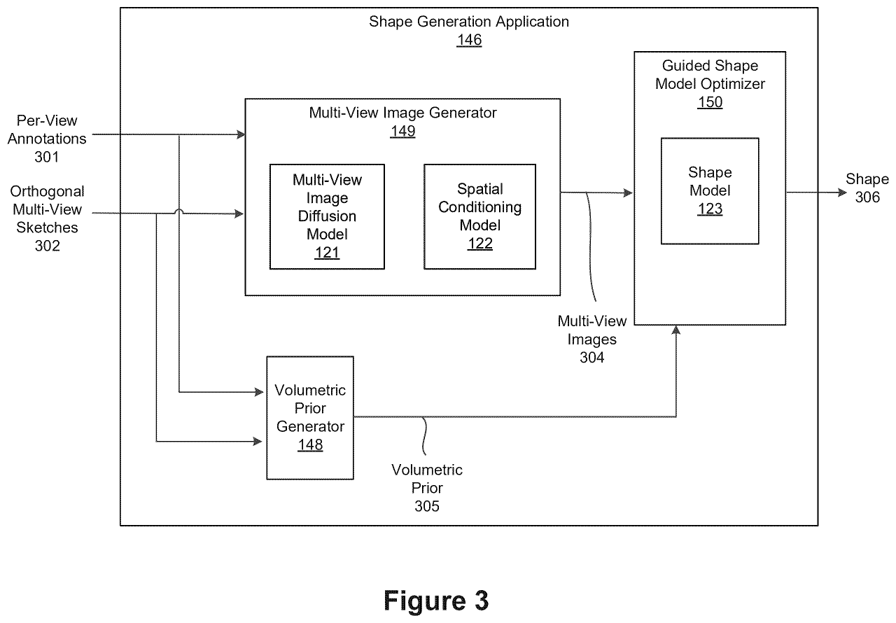

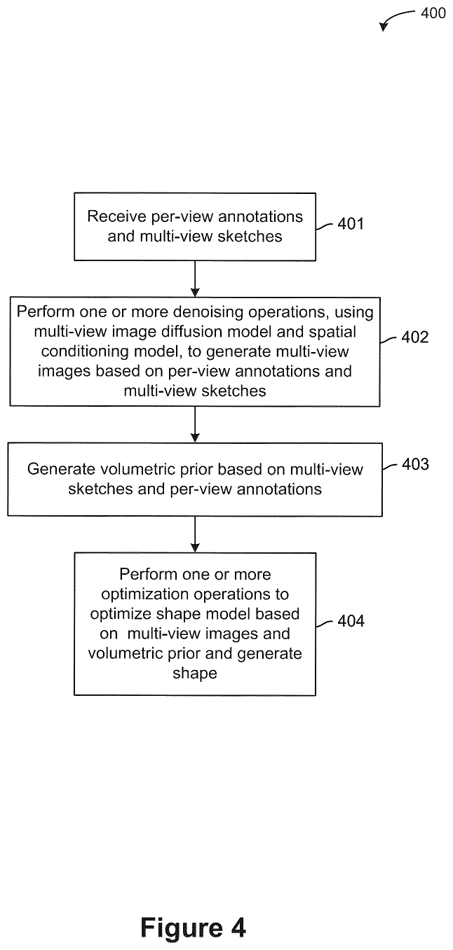

Multi-view image diffusion model 121 is a machine learning model, such as a diffusion model, that processes a spatial conditioning, the per-view annotations, and a latent representation and generates a refined noise estimate. Spatial conditioning model 122 is a machine learning model, such as a neural network, that processes the latent representation and one or more depth maps and generates the spatial conditioning. The shape model 123 includes a geometric representation of an object included in the multi-view images. Volumetric prior generator 148 is a module of shape generation application 146 that processes the orthogonal multi-view sketches and the per-view annotations and generates a volumetric prior. Guided shape model optimizer 150 is a module of shape generation application 146 that performs one or more optimization operations to optimize shape model 123 based on the multi-view images and the volumetric prior and generate the shape. Shape model 123 optimized by guided shape model optimizer 150 is a geometric representation, including but not limited to shape geometric representations based on neural radiance fields (NeRFs), Gaussian splatting, or related implicit or explicit geometric representations, configured to represent the shape consistent with the multi-view images and the per-view annotations. Shape generation application 146 is discussed in greater detail herein in conjunction with at least FIGS. 3 and 4.

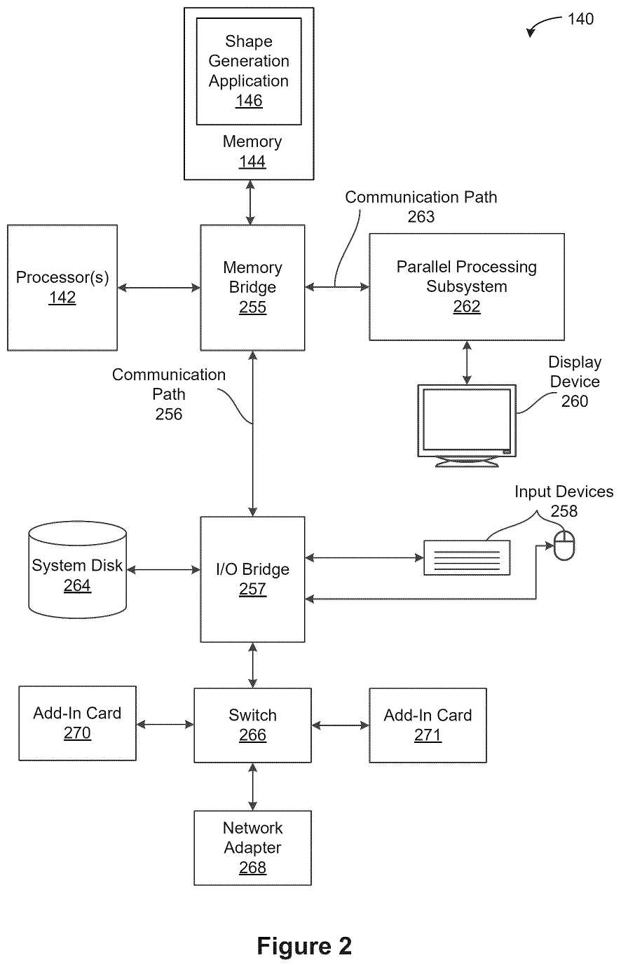

FIG. 2 is a more detailed illustration of computing device 140 of FIG. 1, according to various embodiments. Computing device 140 may include any type of computing system, including, without limitation, a server machine, a server platform, a desktop machine, a laptop machine, a handheld/mobile device, a digital kiosk, an in-vehicle infotainment system, and/or a wearable device. In some embodiments, computing device 140 is a server machine operating in a data center or a cloud computing environment that provides scalable computing resources as a service over a network. In some embodiments, computing device 140 can include one or more similar components as computing device 140.

In various embodiments, computing device 140 includes, without limitation, processor(s) 142 and memory(ies) 144 coupled to a parallel processing subsystem 262 via a memory bridge 255 and a communication path 263. Memory bridge 255 is further coupled to an I/O bridge 257 via a communication path 256, and I/O bridge 257 is, in turn, coupled to a switch 266.

In one embodiment, I/O bridge 257 is configured to receive user input information from optional input devices 258, such as a keyboard, mouse, touch screen, or sensor data analysis (e.g., evaluating gestures, speech, or other information about one or more users in a field of view or sensory field of one or more sensors), and forward the input information to processor(s) 142 for processing. In some embodiments, computing device 140 may be a server machine in a cloud computing environment. In such embodiments, computing device 140 may not include input devices 258 but may receive equivalent input information by receiving commands (e.g., responsive to one or more inputs from a remote computing device) in the form of messages transmitted over a network and received via network adapter 268. In some embodiments, switch 266 is configured to provide connections between I/O bridge 257 and other components of computing device 140, such as a network adapter 268 and various add in cards 270 and 271.

In some embodiments, I/O bridge 257 is coupled to a system disk 264 that may be configured to store content and applications and data for use by processor(s) 142 and parallel processing subsystem 262. In one embodiment, system disk 264 provides non-volatile storage for applications and data and may include fixed or removable hard disk drives, flash memory devices, and CD-ROM (compact disc read-only-memory), DVD-ROM (digital versatile disc-ROM), Blu-ray, HD-DVD (high-definition DVD), or other magnetic, optical, or solid-state storage devices. In various embodiments, other components, such as universal serial bus or other port connections, compact disc drives, digital versatile disc drives, film recording devices, and similar components, may be connected to I/O bridge 257 as well.

In various embodiments, memory bridge 255 may be a Northbridge chip, and I/O bridge 257 may be a Southbridge chip. In addition, communication paths 256 and 263, as well as other communication paths within computing device 140, may be implemented using any technically suitable protocols, including, without limitation, AGP (Accelerated Graphics Port), HyperTransport, or any other bus or point to point communication protocol known in the art.

In some embodiments, parallel processing subsystem 262 comprises a graphics subsystem that delivers pixels to an optional display device 260 that may be any conventional cathode ray tube, liquid crystal display, light-emitting diode display, and/or similar technologies. In such embodiments, parallel processing subsystem 262 may incorporate circuitry optimized for graphics and video processing, including, for example, video output circuitry. Such circuitry may be incorporated across one or more parallel processing units (PPUs), also referred to herein as parallel processors, included within parallel processing subsystem 262.

In some embodiments, parallel processing subsystem 262 incorporates circuitry optimized for general purpose and/or compute processing. Again, such circuitry may be incorporated across one or more PPUs included within parallel processing subsystem 262, which are configured to perform such general-purpose and/or compute operations. In yet other embodiments, the one or more PPUs included within parallel processing subsystem 262 may be configured to perform graphics processing, general-purpose processing, and/or compute processing operations. System memory 144 includes at least one device driver configured to manage the processing operations of the one or more PPUs within parallel processing subsystem 262. In addition, system memory 144 includes shape generation application 146. Although described herein primarily with respect to shape generation application 146, techniques disclosed herein can also be implemented, either entirely or in part, in other software and/or hardware, such as in parallel processing subsystem 262.

In various embodiments, parallel processing subsystem 262 may be integrated with one or more of the other elements of FIG. 2B to form a single system. For example, parallel processing subsystem 262 may be integrated with processor(s) 142 and other connection circuitry on a single chip to form a system on a chip (SoC).

In some embodiments, processor(s) 142 includes the primary processor of computing device 140, controlling and coordinating operations of other system components. In some embodiments, processor(s) 142 issue commands that control the operation of PPUs. In some embodiments, communication path 263 is a PCI Express link, in which dedicated lanes are allocated to each PPU. Other communication paths may also be used. The PPU advantageously implements a highly parallel processing architecture, and the PPU may be provided with any amount of local parallel processing memory (PP memory).

It will be appreciated that the system shown herein is illustrative and that variations and modifications are possible. The connection topology, including the number and arrangement of bridges, the number of processor(s) 142, and the number of parallel processing subsystems 262, may be modified as desired. For example, in some embodiments, system memory 144 could be connected to processor(s) 142 directly rather than through memory bridge 255, and other devices may communicate with system memory 144 via memory bridge 255 and processor(s) 142. In other embodiments, parallel processing subsystem 262 may be connected to I/O bridge 257 or directly to processor(s) 142, rather than to memory bridge 255. In still other embodiments, I/O bridge 257 and memory bridge 255 may be integrated into a single chip instead of existing as one or more discrete devices. In some embodiments, one or more components shown in FIG. 2B may not be present. For example, switch 266 could be eliminated, and network adapter 268 and add-in cards 270, 271 would connect directly to I/O bridge 257. Lastly, in some embodiments, one or more components shown in FIG. 2B may be implemented as virtualized resources in a virtual computing environment, such as a cloud computing environment. In particular, parallel processing subsystem 262 may be implemented as a virtualized parallel processing subsystem in at least one embodiment. For example, parallel processing subsystem 262 may be implemented as virtual graphics processing unit(s) (vGPU(s)) that renders graphics on virtual machine(s) (VM(s)) executing on server machine(s) whose GPU(s) and other physical resources are shared across one or more VMs.

### Shape Generation Using Orthogonal Multi-View Sketches

FIG. 3 is a more detailed illustration of shape application 146, according to various embodiments. As shown, shape generation application 146 includes, without limitation, multi-view image generator 149, volumetric prior generator 148, and guided shape model optimizer 150. Multi-view image generator 149 includes, without limitation, multi-view image diffusion model 121 and spatial conditioning model 122. Guided shape model optimizer 150 includes, without limitation, shape model 123. In operation, multi-view image generator 149 performs one or more denoising operations using multi-view image diffusion model 121 and spatial conditioning model 122 to process per-view annotations 301 and orthogonal multi-view sketches 302 and generate multi-view images 304. Volumetric prior generator 148 processes per-view annotations 301 and orthogonal multi-view sketches 302 and generates volumetric prior 305. Guided shape model optimizer 150 performs one or more optimization operations to optimize shape model 123 based on multi-view images 304 and volumetric prior 305 and generate shape 306.

Volumetric prior generator 148 processes orthogonal multi-view sketches 302 and per-view annotations 301 and generates volumetric prior 305. Orthogonal multi-view sketches 302 include but are not limited to one or more two-dimensional sketch representations shown as a three-dimensional object from different viewpoints, such as front-view sketches, side-view sketches, top-view sketches, or other orthogonal sketch views, together with sketch strokes, contours, silhouettes, and structural indications drawn for each view. Each sketch included in orthogonal multi-view sketches 302 is accompanied by a corresponding per-view annotation 301 indicating the viewpoint of the sketch (e.g., “front view,” “side view,” “top view”). In some embodiments, volumetric prior generator 148 performs one or more image-processing operations on orthogonal multi-view sketches 302, including segmentation of sketch strokes, extraction of contours and silhouettes, identification of structural edges, and/or related operations. In some embodiments, volumetric prior generator 148 projects segmented contours or silhouettes from each annotated view into a shared three-dimensional coordinate frame using canonical orthographic projection rules (e.g., extruding the front-view silhouette along the Z-axis, extruding the side-view silhouette along the X-axis, or extruding the top-view silhouette along the Y-axis). In some examples, projection operations can include back-projection of two-dimensional contours into volumetric space, ray-based assignment of contour-aligned occupancy constraints, or silhouette-based extrusion aligned with the canonical axes inferred from per-view annotations 301. In some embodiments, volumetric prior generator 148 uses a volume-carving procedure in which a regular three-dimensional grid is initialized based on the span of the object indicated by orthogonal multi-view sketches 302. Grid cells within the projected silhouettes of each sketch are identified using binary masks, and the identified grid cells are then extruded or projected along canonical orthographic axes (e.g., projecting front-view silhouettes along the Z-axis) to carve out an approximate occupancy structure of the object. The carved grid regions from multiple views are intersected or fused to form a coarse voxelized representation (e.g., volumetric prior 305) of the three-dimensional shape. Volumetric prior 305 includes three-dimensional projections from multiple orthographic views that are combined to form a coarse volumetric representation that encodes approximate object extent, occupancy structure, or depth intervals inferred from orthogonal multi-view sketches 302. Volumetric prior 305 includes but is not limited to coarse volumetric information representing an approximate spatial extent, occupancy distribution, or depth structure of the three-dimensional object. In some embodiments, volumetric prior 305 includes a discretized signed distance function (SDF) derived from the coarse voxelized volume, where each grid cell stores an approximate signed distance to the inferred surface of the object.

Multi-view image generator 149 performs one or more denoising operations, using multi-view image diffusion model 121 and spatial conditioning model 122, to process per-view annotations 301 and orthogonal multi-view sketches 302 and generate multi-view images 304. Per-view annotations 301 include but are not limited to textual descriptions associated with each view included in orthogonal multi-view sketches 302, such as “top view”, “side view”, “front view”, and/or the like. In some embodiments, multi-view image generator 149 includes a depth map generator (not shown) that generates view-dependent depth maps as coarse depth estimates based on orthogonal multi-view sketches 302. In some embodiments, multi-view image diffusion model 121 includes a pre-trained diffusion model, such as Photorealistic Stable Diffusion v1.5, that encodes orthogonal multi-view sketches 302 into a latent representation Zₜ using an encoder. In some embodiments, the latent representation Zₜ is generated by a sketch encoder or variational autoencoder that processes orthogonal multi-view sketches 302 and generates a compact multi-view latent representation that captures structural, semantic, and view-dependent information for the object. In some embodiments, Zₜ is initialized as Gaussian noise and iteratively refined during successive denoising operations under guidance from per-view annotations 301. In some embodiments, per-view annotations 301 are further processed to generate an annotation embedding Eₐₙₙ that is provided as an input to one or more layers of a U-Net denoising network included in multi-view image diffusion model 121. In some examples, the U-Net denoising network processes the latent representation Zₜ, a spatial conditioning (e.g., image conditioning) generated by spatial conditioning model 122, and the annotation embedding during the denoising operations. In some examples, spatial conditioning model 122 includes a ControlNet architecture that generates the spatial conditioning based on the latent representation Zₜ and the view-dependent depth maps derived from the orthogonal multi-view sketches 302. In some embodiments, multi-view image generator 149 applies a diffusion probabilistic model (DPM)++ adaptive sampling scheduler to adjust step sizes during the denoising operations. In some embodiments, multi-view image generator 149 includes cross-view attention layers in the denoising operations to satisfy cross-view constraints by linking pixel regions across multiple synthesized views included in multi-view images 304, thereby promoting geometric and visual consistency among multi-view images 304. In some examples, during each denoising operation at diffusion timestep t, multi-view image diffusion model 121 encodes per-view annotations 301 and multiview sketches 302 using a variational autoencoder encoder to generate a latent representation Zₜ∈ [symbol] ^{C×H×W}, where C corresponds to the latent channel dimension (e.g., C=4 for a 512×512 input image), and H and W correspond to latent spatial dimensions (e.g., H=64 and W=64 for a 512×512 input image, based on an 8× downsampling factor). The U-Net included in multi-view image diffusion model 121 processes the latent representation Zₜ together with a timestep embedding γ(t) and an annotation embedding Eₐₙₙ to generate a base noise estimate \hat{ϵ}_{base}=f_{U-Net}(Zₜ,γ(t),Eₐₙₙ). Spatial conditioning model 122, implemented using a ControlNet architecture, processes the latent representation Zₜ, one or more view-dependent depth maps D and computes a spatial conditioning H_{ctrl}=f_{ctrlNet}(Zₜ,D). The spatial conditioning

$${H}_{ctrl}^{( l )}$$

are injected into corresponding layers of the U-Net by forming modified activations

$${h}_{mod}^{( l )} = {h}_{U - Net}^{( l )} + {α}_{l} {H}_{ctrl}^{( l )} ,$$

where αₗ denotes a layer-specific scale parameter. Cross-view attention layers aggregate feature maps across all views by computing attention-weighted updates

$${F}_{i}^{′} = {\sum }_{j} soft max ( \frac{{Q}_{i} {K}_{j}^{T}}{\sqrt{d}} ) {V}_{j}$$

for each view i, where (Qᵢ, Kⱼ, Vⱼ) denote query, key, and value projections of intermediate U-Net feature maps for views i and j. The U-Net then generates a refined noise estimate \hat{ϵ}ₜ=f_{denoise} (Zₜ, H_{ctrl}, F_{cross}), where F_{cross} denotes the output of the cross-view attention layers.

Guided shape model optimizer 150 performs one or more optimization operations to optimize shape model 123 based on multi-view images 304 and volumetric prior 305 and generate shape 306. In some embodiments, shape model 123 includes a NeRF representation, and guided shape model optimizer 150 performs NeRF-based optimization by sampling rays from canonical orthographic camera directions (e.g., front, side, top), evaluating density and color predictions along each sampled ray, and computing predicted view images for each corresponding multi-view image 304. The predicted view images are compared to multi-view images 304 to compute one or more reconstruction losses, including photometric losses, silhouette-consistency losses, depth-based losses, or regularization terms derived from volumetric prior 305. In some embodiments, when volumetric prior 305 includes a discretized SDF, guided shape model optimizer 150 includes an SDF-based regularization term that penalizes predicted density values that deviate from SDF-consistent surface locations, thereby promoting surface placement consistent with the coarse volumetric structure inferred from orthogonal multi-view sketches 302. The parameters of the NeRF representation are then updated to minimize the reconstruction losses. In some embodiments, once optimization of the NeRF representation is complete, guided shape model optimizer 150 can generate novel views of shape 306 by rendering the optimized radiance field from arbitrary virtual camera poses, thereby generating view-consistent images of the object from viewpoints not included in multi-view images 304.

In some embodiments, shape model 123 includes a Gaussian-splatting representation, and guided shape model optimizer 150 performs Gaussian-splatting-based optimization by updating three-dimensional Gaussian primitives, including Gaussian positions, scales, covariance matrices, opacity values, and color parameters, based on gradients computed from differences between projected Gaussian renderings and multi-view images 304. In some embodiments, the optimization includes Fast Splatting Gaussian Splatting (FSGS) or related fast-splatting approaches that accelerate forward splatting and gradient computation for large sets of Gaussian primitives. During FSGS-based optimization, Gaussian primitives are projected into canonical orthographic camera axes, enabling differentiable splat-rendered images to be computed without requiring explicit camera intrinsics or extrinsics. In some embodiments, when volumetric prior 305 includes a discretized SDF, guided shape model optimizer 150 constrains Gaussian primitives to align with SDF-defined surface regions by penalizing primitive centers whose signed distance deviates from zero-level-set locations or by projecting Gaussian contributions toward SDF grid cells that correspond to inferred surface positions. Constraining Gaussian primitives to align with SDF-defined surface regions encourages Gaussian primitives to converge toward coherent surface geometry during optimization. In some embodiments, guided shape model optimizer 150 applies sparsity constraints based on volumetric prior 305 to ensure that shape 306 conforms to spatial structure indicated in orthogonal multi-view sketches 302. In some embodiments, once optimization of shape model 123 is complete, guided shape model optimizer 150 applies an FSGS-to-Mesh post-processing procedure to convert the optimized Gaussian representation into a mesh-based shape 306. In some examples, the FSGS-to-Mesh procedure constructs a volumetric density field or Gaussian-accumulated point cloud from the optimized Gaussian primitives, applies an a-shape or related volumetric boundary-extraction algorithm to estimate an explicit surface, and generates mesh vertices, faces, and normals to generate the final triangular mesh representing shape 306. In some embodiments, the optimized Gaussian-splatting representation further enables rendering of novel views of shape 306 from newly provided viewpoints. Because the Gaussian primitives encode a continuous radiance and density field, guided shape model optimizer 150 can generate photorealistic or sketch-consistent novel-view images of the object even from viewpoints not present in multi-view images 304.

FIG. 4 is a flow diagram of method steps for generating shape 306, according to various embodiments. Although the method steps are described in conjunction with the systems of FIGS. 1-3, persons skilled in the art will understand that any system configured to perform the method steps in any order falls within the scope of the present embodiments.

As shown, a method 400 begins with step 401, where shape generation application 146 receives per-view annotations 301 and orthogonal multi-view sketches 302. In some embodiments, orthogonal multi-view sketches 302 include, but are not limited to, one or more two-dimensional sketch representations shown as a three-dimensional object from different viewpoints, such as front-view sketches, side-view sketches, top-view sketches, or other orthogonal sketch views, together with sketch strokes, contours, silhouettes, and structural indications drawn for each view. Each sketch included in orthogonal multi-view sketches 302 is accompanied by a corresponding per-view annotation 301 indicating the viewpoint of the sketch (e.g., “front view,” “side view,” “top view”).

At step 402, multi-view image generator 149 performs one or more denoising operations, using multi-view image diffusion model 121 and spatial conditioning model 122, to generate multi-view images 304 based on per-view annotations 301 and orthogonal multi-view sketches 302. In some embodiments, multi-view image diffusion model 121 includes a pre-trained diffusion model, such as Photorealistic Stable Diffusion v1.5, that encodes per-view annotations 301 and orthogonal multi-view sketches 302 into a latent representation Zₜ using an encoder. In some embodiments, the latent representation Zₜ is generated by a sketch encoder or variational autoencoder that processes orthogonal multi-view sketches 302 and per-view annotations 301 and generates a compact multi-view latent representation that captures structural, semantic, and view-dependent information for the object. In some embodiments, Zₜ is initialized as Gaussian noise and iteratively refined during successive denoising operations under guidance from per-view annotations 301. In some examples, a U-Net denoising network included in multi-view image diffusion model 121 processes the latent representation Zₜ and a spatial conditioning (e.g., image conditioning) generated by spatial conditioning model 122 during the denoising operations. In some examples, spatial conditioning model 122 includes a ControlNet architecture that generates the spatial conditioning based on the latent representation Zₜ and the view-dependent depth maps derived from the orthogonal multi-view sketches 302. In some embodiments, multi-view image generator 149 applies a DPM++ adaptive sampling scheduler to adjust step sizes during the denoising operations. In some embodiments, multi-view image generator 149 includes cross-view attention layers in the denoising operations to satisfy cross-view constraints by linking pixel regions across multiple synthesized views included in multi-view images 304, thereby promoting geometric and visual consistency among multi-view images 304. In some examples, during each denoising operation at diffusion timestep t, multi-view image diffusion model 121 encodes per-view annotations 301 and multiview sketches 302 using a variational autoencoder encoder to generate a latent representation Zₜϵ [symbol] ^{C×H×W}. The U-Net included in multi-view image diffusion model 121 processes the latent representation Zₜ together with a timestep embedding γ(t) and an annotation embedding Eₐₙₙ to generate a base noise estimate \hat{ϵ}_{base}=f_{U-Net}(Zₜ,γ(t),Eₐₙₙ). Spatial conditioning model 122, implemented using a ControlNet architecture, processes the latent representation Zₜ, one or more view-dependent depth maps D and computes a spatial conditioning H_{ctrl}=f_{CtrlNet}(Zₜ,D). The spatial conditioning

$${H}_{ctrl}^{( l )}$$

are injected into corresponding layers of the U-Net by forming modified activations

$${h}_{mod}^{( l )} = {h}_{U - Net}^{( l )} + {α}_{l} {H}_{ctrl}^{( l )} ,$$

where αₗ denotes a layer-specific scale parameter. Cross-view attention layers aggregate feature maps across all views by computing attention-weighted updates Fᵢ′=Σⱼ softmax

$$( \frac{{Q}_{i} {K}_{j}^{T}}{\sqrt{d}} ) {V}_{j}$$

for each view i. The U-Net then generates a refined noise estimate \hat{ϵ}ₜ=f_{denoise}(Zₜ,H_{ctrl},F_{cross}), where F_{cross} denotes the output of the cross-view attention layers.

At step 403, volumetric prior generator 148 generates volumetric prior 305 based on per-view annotations 301 and orthogonal multi-view sketches 302. In some embodiments, volumetric prior generator 148 performs one or more image-processing operations on orthogonal multi-view sketches 302, including segmentation of sketch strokes, extraction of contours and silhouettes, identification of structural edges, and/or the like. In some embodiments, volumetric prior generator 148 projects segmented contours or silhouettes from each annotated view into a shared three-dimensional coordinate frame using canonical orthographic projection rules (e.g., extruding the front-view silhouette along the Z-axis, extruding the side-view silhouette along the X-axis, or extruding the top-view silhouette along the Y-axis). In some examples, projection operations can include back-projection of two-dimensional contours into volumetric space, ray-based assignment of contour-aligned occupancy constraints, or silhouette-based extrusion aligned with canonical axes inferred from per-view annotations 301. In some embodiments, volumetric prior generator 148 uses a volume-carving procedure in which a regular three-dimensional grid is initialized based on the span of the object indicated by orthogonal multi-view sketches 302. Grid cells within the projected silhouettes of each sketch are identified using binary masks, and the identified grid cells are then extruded or projected along canonical orthographic axes (e.g., projecting front-view silhouettes along the Z-axis) to carve out an approximate occupancy structure of the object. The carved grid regions from multiple views are intersected or fused to form a coarse voxelized representation (e.g., volumetric prior 305) of the three-dimensional shape. In some embodiments, volumetric prior 305 includes a discretized SDF derived from the coarse voxelized volume, where each grid cell stores an approximate signed distance to the inferred surface of the object. In some embodiments, steps 402 and 403 can be performed concurrently or sequentially.

At step 404, guided shape model optimizer 150 performs one or more optimization operations to optimize shape model 123 based on multi-view images 304 and volumetric prior 305 and generate shape 306. In some embodiments, shape model 123 includes a NeRF representation, and guided shape model optimizer 150 performs NeRF-based optimization by sampling rays from canonical orthographic camera directions (e.g., front, side, top), evaluating density and color predictions along each sampled ray, and computing predicted view images for each corresponding multi-view image 304. The predicted view images are compared to multi-view images 304 to compute one or more reconstruction losses, including photometric losses, silhouette-consistency losses, depth-based losses, or regularization terms derived from volumetric prior 305. In some embodiments, when volumetric prior 305 includes a discretized SDF, guided shape model optimizer 150 includes an SDF-based regularization term that penalizes predicted density values that deviate from SDF-consistent surface locations, thereby promoting surface placement consistent with the coarse volumetric structure inferred from orthogonal multi-view sketches 302. The parameters of the NeRF representation are then updated to minimize the reconstruction losses. In some embodiments, once optimization of the NeRF representation is complete, guided shape model optimizer 150 can generate novel views of shape 306 by rendering the optimized radiance field from arbitrary virtual camera poses, thereby generating view-consistent images of the object from viewpoints not included in multi-view images 304. In some embodiments, shape model 123 includes a Gaussian-splatting representation, and guided shape model optimizer 150 performs Gaussian-splatting-based optimization by updating three-dimensional Gaussian primitives, including Gaussian positions, scales, covariance matrices, opacity values, and color parameters, based on gradients computed from differences between projected Gaussian renderings and multi-view images 304. In some embodiments, the optimization includes FSGS or related fast-splatting approaches that accelerate forward splatting and gradient computation for large sets of Gaussian primitives. During FSGS-based optimization, Gaussian primitives are projected into canonical orthographic camera axes, enabling differentiable splat-rendered images to be computed without requiring explicit camera intrinsics or extrinsics. In some embodiments, when volumetric prior 305 includes a discretized SDF, guided shape model optimizer 150 constrains Gaussian primitives to align with SDF-defined surface regions by penalizing primitive centers whose signed distance deviates from zero-level-set locations or by projecting Gaussian contributions toward SDF grid cells that correspond to inferred surface positions. Constraining Gaussian primitives to align with SDF-defined surface regions encourages Gaussian primitives to converge toward coherent surface geometry during optimization. In some embodiments, guided shape model optimizer 150 applies sparsity constraints based on volumetric prior 305 to ensure that shape 306 conforms to spatial structure indicated in orthogonal multi-view sketches 302. In some embodiments, once optimization of shape model 123 is complete, guided shape model optimizer 150 applies an FSGS-to-Mesh post-processing procedure to convert the optimized Gaussian representation into a mesh-based shape 306. In some examples, the FSGS-to-Mesh procedure constructs a volumetric density field or Gaussian-accumulated point cloud from the optimized Gaussian primitives, applies an a-shape or related volumetric boundary-extraction algorithm to estimate an explicit surface, and generates mesh vertices, faces, and normals to generate the final triangular mesh representing shape 306. In some embodiments, the optimized Gaussian-splatting representation further enables rendering of novel views of shape 306 from newly provided viewpoints. Because the Gaussian primitives encode a continuous radiance and density field, guided shape model optimizer 150 can generate photorealistic or sketch-consistent novel-view images of the object even from viewpoints not present in multi-view images 304.

In sum, techniques are disclosed for three-dimensional orthogonal multi-view sketches. In some embodiments, the disclosed techniques include a shape generation application that uses a multi-view diffusion model, a spatial conditioning model, and a shape model to process one or more per-view annotations and one or more orthogonal multi-view sketches and to generate a shape. The multi-view image diffusion model is a machine learning model, such as a diffusion model, that processes a spatial conditioning, the per-view annotations, and a latent representation and generates a refined noise estimate. The spatial conditioning model is a machine learning model, such as a neural network, that processes the latent representation and one or more depth maps and generates the spatial conditioning. The shape model includes a geometric representation of an object included in the multi-view images. The shape generation application includes a multi-view image generator, a volumetric prior generator, and a guided shape model optimizer. The multi-view image generator performs one or more denoising operations, using the multi-view image diffusion model and the spatial conditioning model, to process the per-view annotations and the orthogonal multi-view sketches and to generate one or more multi-view images. The volumetric prior generator processes the per-view annotations and the orthogonal multi-view sketches and generates a volumetric prior. The guided shape model optimizer performs one or more optimization operations to optimize the shape model based on the multi-view images and the volumetric prior and to generate the shape.

At least one technical advantage of the disclosed techniques relative to the prior art is that the disclosed techniques do not rely on direct geometric reconstruction or strict multi-view geometric consistency and therefore avoid the heavy computational costs and fragile processing steps associated with conventional geometry-based approaches. Another technical advantage of the disclosed techniques is that the disclosed techniques provide more efficient computation, reduced sensitivity to drawing imperfections, and improved stability across a wide range of sketch inputs, which lowers user effort and renders the shape generation workflow more accessible to non-experts. Yet another technical advantage of the disclosed techniques is the reduction of failure cases and the need for manual correction, resulting in more user-friendly, predictable, and responsive three-dimensional shape generation. These technical advantages provide one or more technological improvements over prior art approaches.
1. In some embodiments, a computer-implemented method for generating three-dimensional shapes includes receiving one or more orthogonal multi-view sketches and one or more per-view annotations, performing, using a first trained machine learning model and a second trained machine learning model, one or more denoising operations to generate one or more multi-view images based on the one or more orthogonal multi-view sketches and the one or more per-view annotations, generating, based on the one or more orthogonal multi-view sketches and the one or more per-view annotations, a volumetric prior, performing, based on the one or more multi-view images and the volumetric prior, one or more optimization operations to optimize a shape model, and generating a three-dimensional shape based on the shape model.
2. The computer-implemented method of clause 1, where the first trained machine learning model includes a diffusion model trained to generate a revised noise estimate based on a spatial conditioning, the one or more per-view annotations, and a latent representation.
3. The computer-implemented method of clauses 1 or 2, where the second trained machine learning model is trained to generate a spatial encoding based on a latent representation and one or more depth maps.
4. The computer-implemented method of any of clauses 1-3, where generating the volumetric prior includes projecting at least one of one or more segmented contours or one or more silhouettes included in the one or more orthogonal multi-view sketches into a three-dimensional coordinate frame using one or more canonical orthographic projection rules.
5. The computer-implemented method of any of clauses 1-4, where generating the volumetric prior includes performing a volume-carving procedure that fuses one or more projected silhouettes associated with the one or more orthogonal multi-view sketches to form a coarse voxelized occupancy representation of the three-dimensional shape.
6. The computer-implemented method of any of clauses 1-5, where the volumetric prior includes a discretized signed distance function derived from the coarse voxelized occupancy representation.
7. The computer-implemented method of any of clauses 1-6, where performing the one or more denoising operations includes aggregating one or more feature maps across a plurality of synthesized views using one or more cross-view attention layers.
8. The computer-implemented method of any of clauses 1-7, where performing the one or more optimization operations includes optimizing a neural radiance field representation included in the shape model.
9. The computer-implemented method of any of clauses 1-8, where optimizing the neural radiance field representation includes sampling one or more rays from one or more canonical orthographic camera directions, evaluating one or more density and color predictions along each sampled ray included in the one or more rays, generating, based on the one or more rays and the one or more density and color predictions, one or more predicted view images, calculating, based on one or more predicted view images and the one or more multi-view images, one or more reconstruction losses, and updating, based on the one or more reconstruction losses, one or more parameters of the neural radiance field representation.
10. The computer-implemented method of any of clauses 1-9, where performing the one or more optimization operations includes optimizing a Gaussian-splatting representation included in the shape model.
11. The computer-implemented method of any of clauses 1-10, where optimizing the Gaussian-splatting representation includes computing, based on one or more differences between one or more differentiable Gaussian renderings and the one or more multi-view images, one or more gradients, and updating, based on the one or more gradients, one or more parameters of one or more Gaussian primitives included in the Gaussian-splatting representation.
12. The computer-implemented method of any of clauses 1-11, where performing the one or more optimization operations includes converting an optimized Gaussian representation included in the shape model into a mesh-based shape using a fast splatting Gaussian splatting-to-mesh procedure.
13. The computer-implemented method of any of clauses 1-12, further including generating one or more novel-view images of the three-dimensional shape by rendering the shape model from one or more camera viewpoints that differ from one or more viewpoints associated with the one or more orthogonal multi-view sketches.
14. In some embodiments, one or more non-transitory computer-readable media store instructions that, when executed by one or more processors, cause the one or more processors to perform the steps of receiving one or more orthogonal multi-view sketches and one or more per-view annotations, performing, using a first trained machine learning model and a second trained machine learning model, one or more denoising operations to generate one or more multi-view images based on the one or more orthogonal multi-view sketches and the one or more per-view annotations, generating, based on the one or more orthogonal multi-view sketches and the one or more per-view annotations, a volumetric prior, performing, based on the one or more multi-view images and the volumetric prior, one or more optimization operations to optimize a shape model, and generating a three-dimensional shape based on the shape model.
15. The one or more non-transitory computer-readable media of clause 14, where generating the volumetric prior includes projecting at least one of one or more segmented contours or one or more silhouettes included in the one or more orthogonal multi-view sketches into a three-dimensional coordinate frame using one or more canonical orthographic projection rules.
16. The one or more non-transitory computer-readable media of clauses 14 or 15, where performing the one or more optimization operations includes optimizing a neural radiance field representation included in the shape model.
17. The one or more non-transitory computer-readable media of any of clauses 14-16, where optimizing the neural radiance field representation includes sampling one or more rays from one or more canonical orthographic camera directions, evaluating one or more density and color predictions along each sampled ray included in the one or more rays, generating, based on the one or more rays and the one or more density and color predictions, one or more predicted view images, calculating, based on one or more predicted view images and the one or more multi-view images, one or more reconstruction losses, and updating, based on the one or more reconstruction losses, one or more parameters of the neural radiance field representation.
18. The one or more non-transitory computer-readable media of any of clauses 14-17, where performing the one or more optimization operations includes optimizing a Gaussian-splatting representation included in the shape model.
19. The one or more non-transitory computer-readable media of any of clauses 14-18, where optimizing the Gaussian-splatting representation includes computing, based on one or more differences between one or more differentiable Gaussian renderings and the one or more multi-view images, one or more gradients, and updating, based on the one or more gradients, one or more parameters of one or more Gaussian primitives included in the Gaussian-splatting representation.
20. In some embodiments, a system includes one or more memories storing instructions, and one or more processors that are coupled to the one or more memories and, when executing the instructions, are configured to receive one or more orthogonal multi-view sketches and one or more per-view annotations, perform, using a first trained machine learning model and a second trained machine learning model, one or more denoising operations to generate one or more multi-view images based on the one or more orthogonal multi-view sketches and the one or more per-view annotations, generate, based on the one or more orthogonal multi-view sketches and the one or more per-view annotations, a volumetric prior, perform, based on the one or more multi-view images and the volumetric prior, one or more optimization operations to optimize a shape model, and generate a three-dimensional shape based on the shape model.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module” or “system.” Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for generating three-dimensional shapes, the method comprising:
receiving one or more orthogonal multi-view sketches and one or more per-view annotations;
performing, using a first trained machine learning model and a second trained machine learning model, one or more denoising operations to generate one or more multi-view images based on the one or more orthogonal multi-view sketches and the one or more per-view annotations;
generating, based on the one or more orthogonal multi-view sketches and the one or more per-view annotations, a volumetric prior;
performing, based on the one or more multi-view images and the volumetric prior, one or more optimization operations to optimize a shape model; and
generating a three-dimensional shape based on the shape model.

2. The computer-implemented method of claim 1, wherein the first trained machine learning model comprises a diffusion model trained to generate a revised noise estimate based on a spatial conditioning, the one or more per-view annotations, and a latent representation.

3. The computer-implemented method of claim 1, wherein the second trained machine learning model is trained to generate a spatial encoding based on a latent representation and one or more depth maps.

4. The computer-implemented method of claim 1, wherein generating the volumetric prior comprises projecting at least one of one or more segmented contours or one or more silhouettes included in the one or more orthogonal multi-view sketches into a three-dimensional coordinate frame using one or more canonical orthographic projection rules.

5. The computer-implemented method of claim 1, wherein generating the volumetric prior comprises performing a volume-carving procedure that fuses one or more projected silhouettes associated with the one or more orthogonal multi-view sketches to form a coarse voxelized occupancy representation of the three-dimensional shape.

6. The computer-implemented method of claim 5, wherein the volumetric prior comprises a discretized signed distance function derived from the coarse voxelized occupancy representation.

7. The computer-implemented method of claim 1, wherein performing the one or more denoising operations comprises aggregating one or more feature maps across a plurality of synthesized views using one or more cross-view attention layers.

8. The computer-implemented method of claim 1, wherein performing the one or more optimization operations comprises optimizing a neural radiance field representation included in the shape model.

9. The computer-implemented method of claim 8, wherein optimizing the neural radiance field representation comprises:
sampling one or more rays from one or more canonical orthographic camera directions;
evaluating one or more density and color predictions along each sampled ray included in the one or more rays;
generating, based on the one or more rays and the one or more density and color predictions, one or more predicted view images;
calculating, based on one or more predicted view images and the one or more multi-view images, one or more reconstruction losses; and
updating, based on the one or more reconstruction losses, one or more parameters of the neural radiance field representation.

10. The computer-implemented method of claim 1, wherein performing the one or more optimization operations comprises optimizing a Gaussian-splatting representation included in the shape model.

11. The computer-implemented method of claim 10, wherein optimizing the Gaussian-splatting representation comprises:
computing, based on one or more differences between one or more differentiable Gaussian renderings and the one or more multi-view images, one or more gradients; and
updating, based on the one or more gradients, one or more parameters of one or more Gaussian primitives included in the Gaussian-splatting representation.

12. The computer-implemented method of claim 1, wherein performing the one or more optimization operations comprises converting an optimized Gaussian representation included in the shape model into a mesh-based shape using a fast splatting Gaussian splatting-to-mesh procedure.

13. The computer-implemented method of claim 1, further comprising generating one or more novel-view images of the three-dimensional shape by rendering the shape model from one or more camera viewpoints that differ from one or more viewpoints associated with the one or more orthogonal multi-view sketches.

14. One or more non-transitory computer-readable media storing instructions that, when executed by one or more processors, cause the one or more processors to perform the steps of:
receiving one or more orthogonal multi-view sketches and one or more per-view annotations;
performing, using a first trained machine learning model and a second trained machine learning model, one or more denoising operations to generate one or more multi-view images based on the one or more orthogonal multi-view sketches and the one or more per-view annotations;
generating, based on the one or more orthogonal multi-view sketches and the one or more per-view annotations, a volumetric prior;
performing, based on the one or more multi-view images and the volumetric prior, one or more optimization operations to optimize a shape model; and
generating a three-dimensional shape based on the shape model.

15. The one or more non-transitory computer-readable media of claim 14, wherein generating the volumetric prior comprises projecting at least one of one or more segmented contours or one or more silhouettes included in the one or more orthogonal multi-view sketches into a three-dimensional coordinate frame using one or more canonical orthographic projection rules.

16. The one or more non-transitory computer-readable media of claim 14, wherein performing the one or more optimization operations comprises optimizing a neural radiance field representation included in the shape model.

17. The one or more non-transitory computer-readable media of claim 16, wherein optimizing the neural radiance field representation comprises:
sampling one or more rays from one or more canonical orthographic camera directions;
evaluating one or more density and color predictions along each sampled ray included in the one or more rays;
generating, based on the one or more rays and the one or more density and color predictions, one or more predicted view images;
calculating, based on one or more predicted view images and the one or more multi-view images, one or more reconstruction losses; and
updating, based on the one or more reconstruction losses, one or more parameters of the neural radiance field representation.

18. The one or more non-transitory computer-readable media of claim 14, wherein performing the one or more optimization operations comprises optimizing a Gaussian-splatting representation included in the shape model.

19. The one or more non-transitory computer-readable media of claim 18, wherein optimizing the Gaussian-splatting representation comprises:
computing, based on one or more differences between one or more differentiable Gaussian renderings and the one or more multi-view images, one or more gradients; and
updating, based on the one or more gradients, one or more parameters of one or more Gaussian primitives included in the Gaussian-splatting representation.

20. A system, comprising:
one or more memories storing instructions; and
one or more processors that are coupled to the one or more memories and, when executing the instructions, are configured to:
receive one or more orthogonal multi-view sketches and one or more per-view annotations;
perform, using a first trained machine learning model and a second trained machine learning model, one or more denoising operations to generate one or more multi-view images based on the one or more orthogonal multi-view sketches and the one or more per-view annotations;
generate, based on the one or more orthogonal multi-view sketches and the one or more per-view annotations, a volumetric prior;
perform, based on the one or more multi-view images and the volumetric prior, one or more optimization operations to optimize a shape model; and
generate a three-dimensional shape based on the shape model.
